(19) United States
(12) Patent Application Publication
(10) Pub. No.: US 2026/0324415 A1
(43) Pub. Date: Oct. 15, 2026

(54) SEMICONDUCTOR PACKAGE INCLUDING HEAT DISSIPATION STRUCTURE AND METHOD OF MANUFACTURING THE SAME

(71) Applicant: SAMSUNG ELECTRONICS CO., LTD., Suwon-si (KR)

(72) Inventor: Dongwoon Park, Suwon-si (KR)

(73) Assignee: SAMSUNG ELECTRONICS CO., LTD., Suwon-si (KR)

(21) Appl. No.: 19/367,313

(22) Filed: Oct. 23, 2025

(30) Foreign Application Priority Data
Apr. 10, 2025 (KR) 10-2025-0046810

(51) Int. Cl. H10W 40/22; H10W 72/50; H10W 90/00; H10P 54/00; H10W 46/00

(52) U.S. Cl. CPC H10W 40/22; H10W 72/50; H10W 90/00; H10W 90/701; H10P 54/00; H10W 46/00; H10W 90/724

(57) ABSTRACT

A semiconductor package includes a lower package including: a lower package substrate; and a lower semiconductor device above the lower package substrate; an upper package on the lower package in a first direction intersecting with an upper surface of the lower package, the upper package including: an upper package substrate on the upper surface of the lower package; and an upper semiconductor device above an upper surface of the upper package substrate; and a heat dissipation structure above the lower package and spaced apart from the upper semiconductor device in a second direction intersecting with the first direction. An upper surface of the heat dissipation structure is inclined at a an angle with respect to the upper semiconductor device.

### CROSS-REFERENCE TO RELATED APPLICATION

This application claims priority under 35 U.S.C. §119 to Korean Patent Application No. 10-2025-0046810, filed on Apr. 10, 2025, in the Korean Intellectual Property Office, the disclosure of which is incorporated by reference herein in its entirety.

### BACKGROUND

### 1. Field

The present disclosure relates to a semiconductor package and a method of manufacturing the same.

### 2. Description of Related Art

Due to advances in the electronics industry, there is a growing demand for higher functionality, higher speed, and miniaturization of electronic components, leading to increases in integration density and operating speed of semiconductor chips (devices). Higher integration density and higher functionality of semiconductor chips increase heat generated in the semiconductor chips.

To satisfy the demand for higher integration density and higher functionality of electronic components, the performance and lifespan of semiconductor chips may be enhanced by effectively dissipating heat generated in the semiconductor chips outside. If heat generated in a semiconductor chip is not dissipated, the heat may decrease the performance of the semiconductor chip, and in severe cases, the semiconductor chip may be damaged and may not perform the intended function thereof.

### SUMMARY

One or more example embodiments of the present disclosure provide a semiconductor package in which the efficiency of dissipating internal heat may be increased.

According to an aspect of the disclosure, a semiconductor package may include: a lower package including: a lower package substrate; and a lower semiconductor device above the lower package substrate; an upper package on the lower package in a first direction intersecting with an upper surface of the lower package, the upper package including: an upper package substrate on the upper surface of the lower package; and an upper semiconductor device above an upper surface of the upper package substrate; and a heat dissipation structure above the lower package and spaced apart from the upper semiconductor device in a second direction intersecting with the first direction, wherein an upper surface of the heat dissipation structure is inclined at an angle with respect to the upper semiconductor device.

According to an aspect of the disclosure, a semiconductor package may include: a lower package including: a lower package substrate; and a lower semiconductor device above the lower package substrate; an upper package on the lower package in a first direction intersecting with an upper surface of the lower package, the upper package including: an upper package substrate on the upper surface of the lower package; and an upper semiconductor device above an upper surface of the upper package substrate; and a heat dissipation structure above the lower package and spaced apart from a side surface of the upper semiconductor device in a second direction intersecting with the first direction with a gap in between, wherein a width of the gap in the second direction decreases as a distance from the lower package in the first direction increases, and wherein one end of an upper surface of the heat dissipation structure closest to the upper semiconductor device is closer to an upper surface of the lower package substrate than another end of the upper surface of the heat dissipation structure farthest from the upper semiconductor device.

According to an aspect of the disclosure, a semiconductor package may include: a lower package including: a lower package substrate; and a lower semiconductor device above the lower package substrate; an upper package on the lower package in a first direction intersecting with an upper surface of the lower package, the upper package including: an upper package substrate on the upper surface of the lower package; and an upper semiconductor device above an upper surface of the upper package substrate; a heat dissipation structure above the lower package and spaced apart from a side surface of the upper semiconductor device in a second direction intersecting with the first direction with a gap in between; connection bumps between the heat dissipation structure and the upper package substrate, wherein the connection bumps are spaced apart from each other by a predetermined distance in the second direction; an external connection pad on a lower surface of the lower package substrate and including a conductive material; and an external connection terminal coupled to the external connection pad, wherein respective lengths of the connection bumps in the first direction increase as a distance between the respective one of the connection bumps and the upper semiconductor device increases in the second direction, wherein an upper surface of the heat dissipation structure is inclined at an angle with respect to the upper semiconductor device, wherein one end of the upper surface of the heat dissipation structure closest to the upper semiconductor device is below an upper surface of the upper semiconductor device in the first direction, and wherein another end of the upper surface of the heat dissipation structure farthest from the upper semiconductor device is above the upper surface of the upper semiconductor device in the first direction.

According to another aspect of the disclosure, a method of manufacturing a semiconductor package may include: stacking an upper package substrate panel on a lower package substrate panel in a first direction intersecting with an upper surface of the lower package substrate panel, disposing a wiring connection pad at one side of the upper package substrate panel and disposing a plurality of pre-heat dissipation connection bumps at the other side of the upper package substrate panel spaced apart from the one side of the upper package substrate panel in a second direction intersecting with the first direction, and disposing a heat dissipation structure connected to the plurality of pre-heat dissipation connection bumps above the upper package substrate panel such that an upper surface of the heat dissipation structure is inclined with respect to an upper surface of the upper package substrate panel.

The wiring connection pad may be disposed on a first area of the upper package substrate panel. The plurality of pre-heat dissipation connection bumps may be disposed on a second area adjacent to the first area and a third area spaced apart from the first area with the second area in between. A distance between two of the plurality of pre-heat dissipation connection bumps, which are adjacent in the second direction and on the second area, may be shorter than a distance between two of the plurality of pre-heat dissipation connection bumps, which are adjacent in the second direction and on the third area.

The disposing of the heat dissipation structure such that the upper surface of the heat dissipation structure is inclined with respect to the upper surface of the upper package substrate panel may include forming a connection bump by merging a plurality of pre-heat dissipation connection bumps, which are adjacent in the second direction and on the second area.

The respective connection bumps may have a height in the first direction which increases as a distance of the respective one of the connection bumps in the second direction from the one side of the upper package substrate panel toward another side of the upper package substrate panel increases.

The method may further include disposing an upper semiconductor device connected to the wiring connection pad above the upper package substrate panel and forming an upper package substrate and a lower package substrate by cutting the upper package substrate panel and the lower package substrate panel along a first sawing line extending in the second direction and a second sawing line extending in a third direction intersecting with the first direction and the second direction.

The upper surface of the heat dissipation structure may be inclined at an angle with respect to the upper semiconductor device.

The heat dissipation structure may be coupled to the upper package substrate through a connection bump formed based on the plurality of pre-heat dissipation connection bumps being melted. The wiring connection pad may be disposed on a first area of the upper package substrate panel. The plurality of pre-heat dissipation connection bumps may be disposed on a second area adjacent to the first area and a third area spaced apart from the first area with the second area in between. The connection bump on the second area may be formed by combining two of the plurality of pre-heat dissipation connection bumps, which are adjacent in the second direction.

Among the plurality of pre-heat dissipation connection bumps, a plurality of pre-heat dissipation connection bumps spaced apart from each other along a third direction intersecting with the first direction and the second direction may be disposed to form n rows spaced apart from each other along the second direction. A distance between two of the plurality of pre-heat dissipation connection bumps, adjacent in the third direction in an (n-1)-th row, may be shorter than a distance between two of the plurality of pre-heat dissipation connection bumps, adjacent in the third direction in an n-th row.

### BRIEF DESCRIPTION OF THE DRAWINGS

The above and other aspects, features, and advantages will be more apparent from the following description of example embodiments, taken in conjunction with the accompanying drawings, in which:

FIG. 1 is an example layout diagram of a semiconductor package according to one or more example embodiments;

FIG. 2 illustrates an example cross-sectional view taken along line A-A of FIG. 1, according to one or more example embodiments;

FIG. 3 is an example diagram illustrating a semiconductor package of FIG. 2 coupled to an external device, according to one or more example embodiments; and

FIGS. 4, 5, 6, 7, 8, 9, 10, 11 and 12 are example diagrams of intermediate stages for illustrating a method of manufacturing a semiconductor package of FIG. 2, according to one or more example embodiments, and more particularly, FIGS. 4, 6, and 10 are diagrams for illustrating a method of manufacturing a semiconductor package at a panel level, according to one or more example embodiments, FIGS. 8 and 9 illustrate enlarged views of part P of FIG. 6, according to one or more example embodiments, and FIGS. 5, 7, 11, and 12 are diagrams of intermediate stages for illustrating a method of manufacturing a semiconductor package at a panel level, according to one or more example embodiments.

### DETAILED DESCRIPTION

Hereinafter, example embodiments are described with reference to the accompanying drawings. The same reference numerals are used for the same components in the drawings, and duplicate descriptions thereof are omitted.

The words and terms used in the present disclosure are not to be construed as limited to common or dictionary meanings but may be construed as meanings and concepts coinciding with the technical idea of the present disclosure based on the principle that the present disclosure may appropriately define the concept of the term to explain the present disclosure. Therefore, it will be understood that the one or more example embodiments described herein and the configurations illustrated in the drawings are only exemplary embodiments, rather than fully covering the technical idea of the present disclosure, and thus, one or more example embodiments may be modified with various equivalents and modification examples.

In the following description, a singular expression includes a plural expression unless otherwise defined by context. It should be understood that terms such as “comprise or include” and “configure” are intended to indicate the presence of a feature, a number, a step, an operation, an element, a component, or a combination thereof described herein and not intended to exclude the possibility of the presence or addition of one or more other features, numbers, steps, operations, elements, components, or combinations thereof in advance.

In the present disclosure, a singular expression includes a plural expression unless otherwise defined by context. Furthermore, although the terms such as first and second may be used to describe various elements, these elements are not limited by the above terms, and the terms may be used to distinguish one element from another. Within the scope of the present disclosure, a first element may be referred to as a second element, and similarly, a second element may be referred to as a first element. Further, in the accompanying drawings, the shapes and sizes of elements may be exaggerated for clearer description.

Furthermore, expressions such as above, upper portion, below, lower portion, side surface, front surface, and rear surface are represented herein with respect to a direction illustrated in a drawing and may be represented otherwise if the direction of a corresponding element changes. The shapes and sizes of elements may be exaggerated for clarity in the drawings.

As used herein, expressions such as “at least one of,” when preceding a list of elements, modify the entire list of elements and do not modify the individual elements of the list. For example, the expression, "at least one of a, b, or c," should be understood as including only a, only b, only c, both a and b, both a and c, both b and c, or all of a, b, and c.

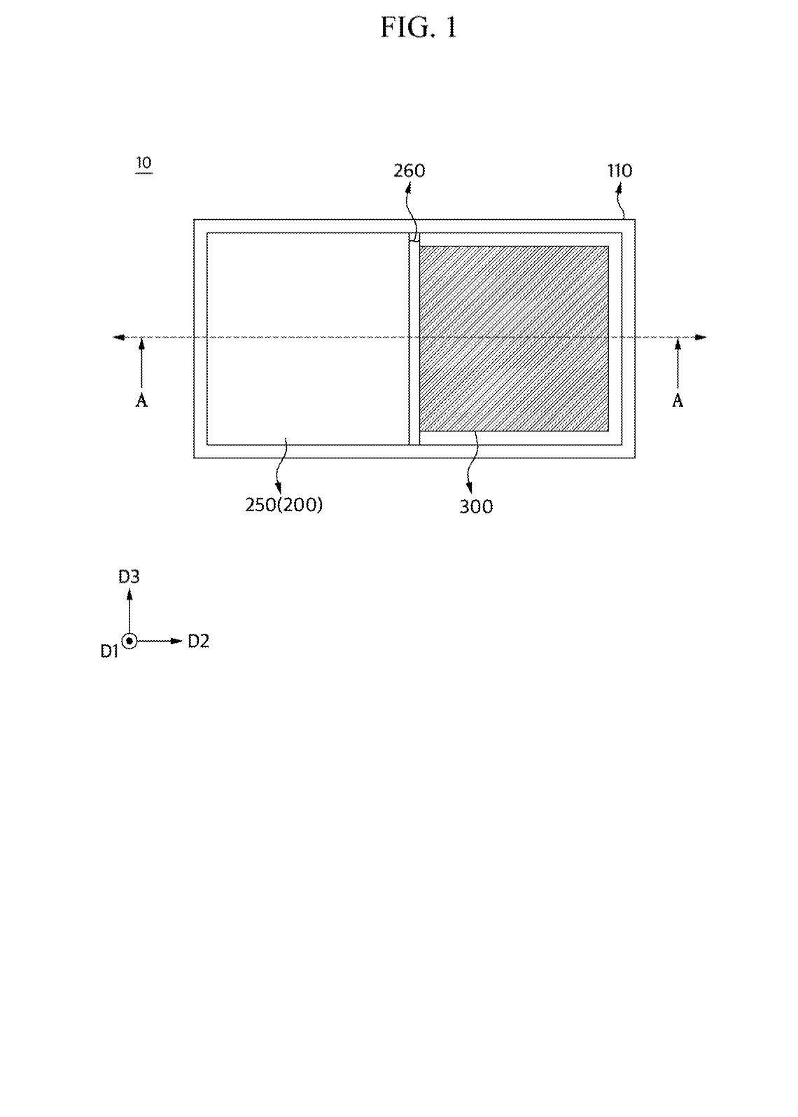

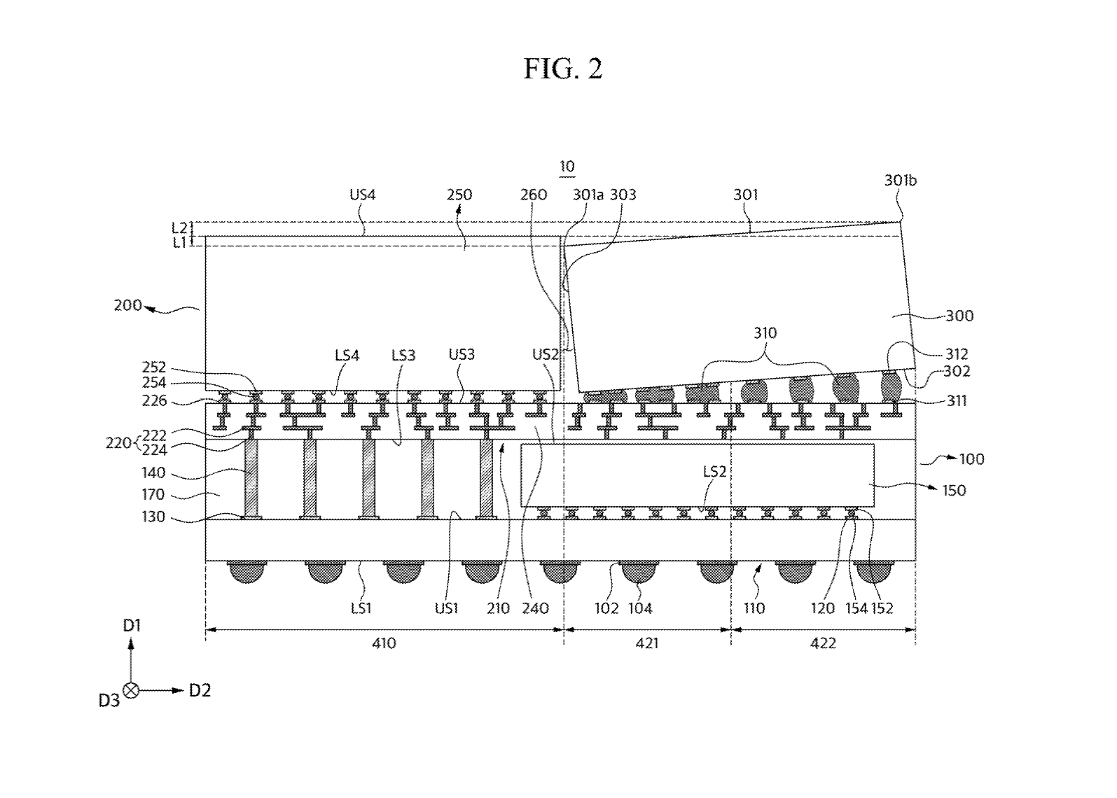

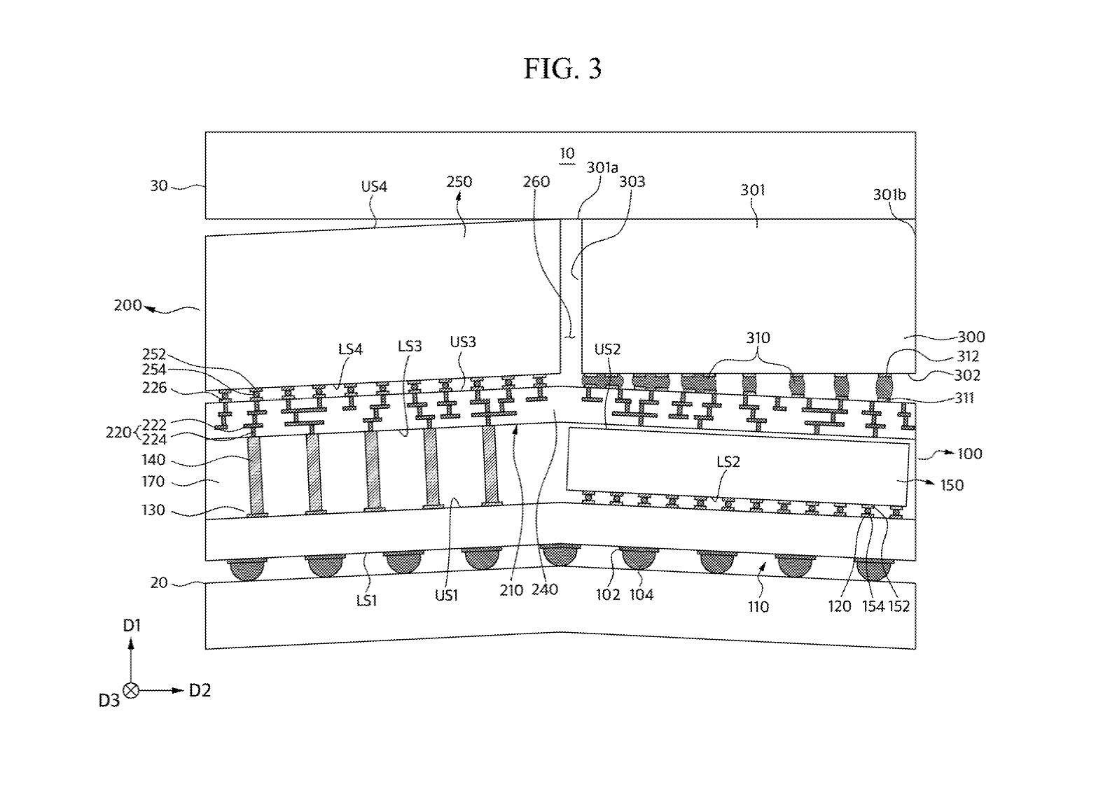

FIG. 1 is an example layout diagram of a semiconductor package 10 according to one or more example embodiments, FIG. 2 illustrates an example cross-sectional view taken along line A-A of FIG. 1 according to one or more example embodiments, and FIG. 3 is an example diagram illustrating the semiconductor package 10 of FIG. 2 coupled to an external device 20 according to one or more example embodiments.

Referring to FIGS. 1 and 2, the semiconductor package 10 according to one or more example embodiments may be a semiconductor package of a package-on-package type, in which a plurality of semiconductor packages are stacked and electrically connected. However, the semiconductor package baccording to one or more example embodiments is not limited thereto and may be a semiconductor package of a system-in-package or package-in-package type, in which a plurality of semiconductor chips or package substrates are electrically connected within a single package or may include various types of semiconductor packages in addition to the above-described packages. Hereinafter, to facilitate understanding, it is described as an example that the semiconductor package 10 according to one or more example embodiments is the package-on-package type.

According to one or more example embodiments, the semiconductor package 10 may include a lower package 100, an upper package 200, and a heat dissipation structure 300. The lower package 100 and the upper package 200 according to one or more example embodiments may be arranged in a first direction D1. The first direction D1 may refer to a direction in which the lower package 100 and the upper package 200 are stacked. A second direction D2 may refer to a direction parallel to an upper surface of the lower package 100 and intersecting with the first direction D1. A third direction D3 may refer to a direction intersecting with the first direction D1 and the second direction D2. The first direction D1 and the second direction D2 may be perpendicular to each other, the second direction D2 and the third direction D3 may be perpendicular to each other, and the third direction D3 and the first direction D1 may be perpendicular to each other.

According to one or more example embodiments, the lower package 100 may include a lower package substrate 110, a lower conductive structure 140, and a lower semiconductor device 150. The lower package substrate 110 may be a wiring substrate for a package. For example, the lower package substrate 110 may be a printed circuit board (PCB) or a ceramic substrate. Furthermore, the lower package substrate 110 may be a wiring substrate for a panel level package (PLP) manufactured at a panel level.

According to one or more example embodiments, the lower package substrate 110 may include a lower insulating layer and a lower wiring line. The lower insulating layer may be disposed to surround the lower wiring line. The lower insulating layer may be disposed to have a single-layer or multilayer structure. The lower insulating layer may include an organic material such as a photo-imageable dielectric (PID) material and a photosensitive polyimide (PSPI) material. For example, the PID material may include at least one of PSPI, polybenzoxazole, a phenol-based polymer, and a benzocyclobutene-based polymer but is not limited thereto.

According to one or more example embodiments, the lower wiring line may include a conductive material. The lower wiring line may include at least one of copper (Cu), aluminum (Al), tin (Sn), indium (In), lead (Pb), zinc (Zn), nickel (Ni), gold (Au), silver (Ag), antimony (Sb), bismuth (Bi), and any combination thereof, but one or more example embodiments are not limited thereto.

According to one or more example embodiments, an external connection pad 102 may be disposed on a lower surface LS1 of the lower package substrate 110. The external connection pad 102 may be disposed to be exposed from a lowermost layer of the lower package substrate 110. The external connection pad 102 may be provided as one of a plurality of external connection pads 102 disposed on the lower surface LS1 of the lower package substrate 110 and spaced apart from each other. The external connection pad 102 may include a conductive material. For example, the external connection pad 102 may include aluminum (Al) or copper (Cu), and the external connection pad 102 may have a circular shape or a rectangular shape but is not limited thereto.

According to one or more example embodiments, an external connection terminal 104 configured to be electrically connected to an external device 20 may be disposed on the external connection pad 102. The external connection terminal 104 may include a conductive material. The external connection terminal 104 may be attached to the external connection pad 102 to be electrically connected to the external connection pad 102, and accordingly, the external connection terminal 104 may be electrically connected to the lower wiring line disposed within the lower package substrate 110. The external connection terminal 104 may have a spherical shape or an ellipsoidal shape but is not limited thereto.

According to one or more example embodiments, each of a first lower connection pad 120 and a second lower connection pad 130 may be disposed on an upper surface US1 of the lower package substrate 110. The first lower connection pad 120 and the second lower connection pad 130 may be provided as a plurality of first lower connection pads 120 and a plurality of second lower connection pads 130, respectively, on the upper surface US1 of the lower package substrate 110. The first lower connection pads 120 may be spaced apart from each other, and the second lower connection pads 130 may be spaced apart from each other. The first lower connection pad 120 and the second lower connection pad 130 may be disposed in different areas on the upper surface US1 of the lower package substrate 110. For example, when viewed from the upper surface US1 of the lower package substrate 110, the first lower connection pad 120 may be disposed in a right area with respect to a vertical line passing through the center of the lower package substrate 110 and the second lower connection pad 130 may be disposed in a left area with respect to the vertical line.

According to one or more example embodiments, the first lower connection pad 120 and the second lower connection pad 130 may include a conductive material. For example, the first lower connection pad 120 and the second lower connection pad 130 may include at least one material selected from materials such as copper (Cu), aluminum (Al), and gold (Au). The first lower connection pad 120 and the second lower connection pad 130 may be electrically connected to the lower wiring line of the lower package substrate 110. Accordingly, each of the first lower connection pad 120 and the second lower connection pad 130 may be electrically connected to an external device 20 through the lower wiring line, the external connection pad 102, and the external connection terminal 104.

According to one or more example embodiments, the lower conductive structure 140 may be disposed above the upper surface US1 of the lower package substrate 110. Specifically, the lower conductive structure 140 may be disposed between the lower package substrate 110 and an upper package substrate 210 described in more detail below. The lower conductive structure 140 may be formed in an area overlapping with a wiring structure 220, described in more detail below, with respect to the first direction D1. The lower conductive structure 140 may be disposed on the second lower connection pad 130. In other words, a lower end of the lower conductive structure 140 may be in contact with an upper end of the second lower connection pad 130, and an upper end of the lower conductive structure 140 may be in contact with a lower end of the wiring structure 220 of the upper package substrate 210, to be described in more detail below. Accordingly, the lower conductive structure 140 may electrically connect the second lower connection pad 130 to the wiring structure 220 to electrically connect the lower semiconductor device 150 to an upper semiconductor device 250, to be described in more detail below.

According to one or more example embodiments, the lower conductive structure 140 may be surrounded by a mold layer 170. The lower conductive structure 140 may penetrate the mold layer 170 and may extend in the first direction D1. The lower conductive structure 140 may electrically connect the wiring structure 220 of the upper package substrate 210 to the lower wiring line of the lower package substrate 110. The lower conductive structure 140 may include a conductive material. For example, the lower conductive structure 140 may include copper (Cu).

According to one or more example embodiments, the lower semiconductor device 150 may be a semiconductor chip. For example, the lower semiconductor device 150 may include a logic chip. Specifically, the logic chip may include a microprocessor, an analog device, or a digital signal processor. For example, the logic chip may be a microprocessor such as a central processing unit (CPU), a graphic processing unit (GPU), and an application processor (AP), an analog device, or a digital signal processor. However, the lower semiconductor device 150 is not limited to the above-described examples and may include a memory chip, an image chip including a charge coupled device (CCD) image sensor or a complementary metal oxide semiconductor (CMOS) image sensor, or a system on chip (SoC) that integrates all essential elements of a system, such as a microprocessor, a memory, and/or an input/output interface, on a single chip. According to one or more example embodiments, the memory chip may include a volatile memory chip such as dynamic random access memory (DRAM) and static random access memory (SRAM) or a nonvolatile memory chip such as phase-change random access memory (PRAM), magnetoresistive random access memory (MRAM), ferroelectric random access memory (FeRAM), and resistive random access memory (RRAM).

According to one or more example embodiments, the lower semiconductor device 150 may include at least one circuit element. The circuit element of the lower semiconductor device 150 may be electrically connected to the lower package substrate 110 through a plurality of first connection pads 152, a plurality of first lower connection bumps 154, and the plurality of first lower connection pads 120, and accordingly, the circuit element of the lower semiconductor device 150 may exchange electrical signals with an external device 20. Further, the circuit element of the lower semiconductor device 150 may be electrically connected to the lower wiring line disposed within the lower package substrate 110 to exchange electrical signals with the upper semiconductor device 250.

According to one or more example embodiments, the plurality of first connection pads 152 may be disposed below the lower semiconductor device 150. The plurality of first connection pads 152 may be disposed on a lower surface LS2 of the lower semiconductor device 150. The plurality of first connection pads 152 may be spaced apart from each other. For example, the plurality of first connection pads 152 may be disposed at positions corresponding one-to-one with the plurality of first lower connection pads 120 disposed on the lower package substrate 110. The plurality of first connection pads 152 may include a conductive material. For example, the plurality of first connection pads 152 may include at least one of copper (Cu), aluminum (Al), tin (Sn), indium (In), lead (Pb), zinc (Zn), nickel (Ni), gold (Au), silver (Ag), antimony (Sb), bismuth (Bi), and a combination thereof, but these are merely examples.

According to one or more example embodiments, the plurality of first lower connection bumps 154 may be disposed on the plurality of first connection pads 152. For example, the plurality of first lower connection bumps 154 may be disposed between the plurality of first connection pads 152 and the plurality of first lower connection pads 120. The plurality of first lower connection bumps 154 may include a conductive material. For example, the plurality of first lower connection bumps 154 may be a micro bump, a solder bump, or a solder ball but are not limited thereto. For example, the plurality of first lower connection bumps 154 may have various shapes such as a land, a ball, a pin, and a pillar. Furthermore, the number, intervals, and arrangement of the plurality of first connection pads 152 and the plurality of first lower connection bumps 154 are not limited to those illustrated in the drawings and may be variously modified depending on design.

According to one or more example embodiments, the lower semiconductor device 150 may be disposed above the lower package substrate 110. For example, the lower semiconductor device 150 may be flip-chip bonded and mounted on the lower package substrate 110 via the plurality of first connection pads 152 and the plurality of first lower connection bumps 154 described above, but is not limited thereto.

According to one or more example embodiments, the mold layer 170 may surround the lower conductive structure 140 and the lower semiconductor device 150. Specifically, the mold layer 170 may surround a side surface of the lower conductive structure 140, and an upper surface of the mold layer 170 and an upper surface of the lower conductive structure 140 may be positioned on the same plane. The upper surface of the mold layer 170 may be in contact with a lower surface LS3 of the upper package 200. The mold layer 170 may surround the second lower connection pad 130. The mold layer 170 may surround the lower semiconductor device 150. The mold layer 170 may surround each of a side surface and an upper surface US2 of the lower semiconductor device 150.

According to one or more example embodiments, the mold layer 170 may comprise a resin including epoxy or polyimide. For example, the resin may include a bisphenol-group epoxy resin, a polycyclic aromatic epoxy resin, an o-cresol novolac epoxy resin, a biphenyl-group epoxy resin, or a naphthalene-group epoxy resin.

According to one or more example embodiments, the upper package 200 may be disposed on the lower package 100. Specifically, the upper package 200 and the lower package 100 may be arranged in the first direction D1.

According to one or more example embodiments, the upper package 200 may include the upper package substrate 210 and the upper semiconductor device 250. The upper package substrate 210 may be a substrate for a PLP manufactured at a panel level. However, one or more example embodiments are not limited to this example, and the upper package substrate 210 may be a substrate for a wafer level package (WLP) manufactured at a wafer level.

According to one or more example embodiments, the upper package substrate 210 may include the wiring structure 220. The wiring structure 220 may be disposed in an area overlapping with an area where the second lower connection pad 130 or the lower conductive structure 140 is disposed in the first direction D1. Further, the wiring structure 220 may be disposed to overlap with the lower semiconductor device 150 in the first direction D1.

According to one or more example embodiments, the wiring structure 220 may include a wiring pattern 222 and a wiring via 224. The wiring pattern 222 and the wiring via 224 may be collectively referred to as a wiring line 222 and 224. The wiring pattern 222 may extend in the second direction D2 and/or the third direction D3. The wiring via 224 may extend in the first direction D1. The wiring pattern 222 may be disposed within an identical layer. Further, the wiring pattern 222 may be disposed to form layers spaced apart and stacked in the first direction D1. The wiring via 224 may vertically connect the wiring patterns 222 disposed individually in the layers spaced apart and stacked in the first direction D1. In other words, the wiring line 222 and 224 may have a multilayer structure in which at least one wiring pattern 222 and at least one wiring via 224 are alternately stacked. Furthermore, the number or arrangement of the wiring lines 222 and 224 is not limited to those one or more example embodiments illustrated in the drawings.

According to one or more example embodiments, the wiring line 222 and 224 may include a conductive material. For example, the wiring line 222 and 224 may include at least one of copper (Cu), aluminum (Al), tin (Sn), indium (In), tungsten (W), lead (Pb), zinc (Zn), nickel (Ni), gold (Au), silver (Ag), antimony (Sb), bismuth (Bi), titanium (Ti), and a combination thereof, but is not limited thereto.

According to one or more example embodiments, the wiring line 222 and 224 may be electrically connected to the lower package 100. Specifically, the wiring line 222 and 224 may be electrically connected to the lower conductive structure 140. Accordingly, the wiring line 222 and 224 may be electrically connected to an external device 20 through the lower conductive structure 140. The wiring line 222 and 224 may be electrically connected to a wiring structure and/or the circuit element of the lower semiconductor device 150 of the lower package 100 via the lower conductive structure 140.

According to one or more example embodiments, a plurality of wiring connection pads 226 may be disposed on the wiring structure 220. The plurality of wiring connection pads 226 may be disposed on an upper surface US3 of the wiring structure 220. The plurality of wiring connection pads 226 may be spaced apart from each other. The plurality of wiring connection pads 226 may include a conductive material. The wiring connection pads 226 may be electrically connected to the wiring line 222 and 224.

According to one or more example embodiments, the wiring pattern 222 and the wiring via 224 may be surrounded by an insulating layer 240. Although the insulating layer 240 surrounding the wiring lines 222 and 224 is illustrated as a single layer, the insulating layer 240 may be a multilayer surrounding the wiring lines 222 and 224. For example, the insulating layer 240 may include an organic material such as a PID material and a PSPI material. For example, the PID material may include at least one of PSPI, polybenzoxazole, a phenol-based polymer, and a benzocyclobutene-based polymer. As another example, the insulating layer 240 may include an inorganic dielectric material such as silicon nitride and silicon oxide.

According to one or more example embodiments, the upper semiconductor device 250 may be a semiconductor chip. For example, the upper semiconductor device 250 may be a semiconductor chip of a type different from that of the lower semiconductor device 150. Further, the upper semiconductor device 250 may be a semiconductor chip that generates heat less than the lower semiconductor device 150. According to one or more example embodiments, the upper semiconductor device 250 may include a memory chip, and the lower semiconductor device 150 may include a logic chip as described above. For example, the upper semiconductor device 250 may include a volatile memory chip such as DRAM and SRAM or a nonvolatile memory chip such as PRAM, MRAM, FeRAM, and RRAM. However, the upper semiconductor device 250 is not limited thereto and may include a logic chip including a CPU, a GPU, a microprocessor, an image chip, and an SoC.

According to one or more example embodiments, the upper semiconductor device 250 may be disposed above the upper package substrate 210. An upper surface US4 of the upper semiconductor device 250 may be parallel to the upper surface US3 of the upper package substrate 210. The upper semiconductor device 250 may be disposed above the wiring structure 220. The upper semiconductor device 250 may overlap with the wiring structure 220 in the first direction D1.

According to one or more example embodiments, the upper semiconductor device 250 may be mounted on the upper package substrate 210 via a plurality of second connection pads 252 and a plurality of second connection bumps 254. For example, the upper semiconductor device 250 may be flip-chip bonded on the upper package substrate 210 but is not limited thereto.

According to one or more example embodiments, the plurality of second connection pads 252 may be disposed on a lower surface LS4 of the upper semiconductor device 250. The plurality of second connection pads 252 may be disposed on the lower surface LS4 of the upper semiconductor device 250, and the plurality of second connection pads 252 may be spaced apart from each other. The plurality of second connection pads 252 may include a conductive material, and as an example, may include a material identical or similar to that of the plurality of first connection pads 152.

According to one or more example embodiments, the plurality of second connection bumps 254 may be disposed on the plurality of second connection pads 252. The number of the plurality of second connection bumps 254 may correspond to the number of the plurality of second connection pads 252. Further, the plurality of second connection bumps 254 may correspond one-to-one with the plurality of second connection pads 252. The plurality of second connection bumps 254 may include a conductive material and may include a material identical or similar to that of the plurality of first lower connection bumps 154.

According to one or more example embodiments, the plurality of second connection pads 252 may be electrically connected to a wiring structure and/or a circuit element of the upper semiconductor device 250. The plurality of second connection bumps 254 may be electrically connected to the plurality of second connection pads 252 and electrically connected to the plurality of wiring connection pads 226. The upper semiconductor device 250 may be electrically connected to the wiring structure 220, the lower package substrate 110, and the lower semiconductor device 150, and accordingly, the upper semiconductor device 250 and the lower semiconductor device 150 may exchange electrical signals.

According to one or more example embodiments, the heat dissipation structure 300 may be disposed above the upper package substrate 210. The upper semiconductor device 250 may be disposed above a first area 410 of the upper package substrate 210, and the heat dissipation structure 300 may be disposed above a second area 421 and a third area 422 of the upper package substrate 210. The heat dissipation structure 300 may be spaced apart from the upper semiconductor device 250 in the second direction D2 and disposed above the lower package 100. For example, the heat dissipation structure 300 may overlap with the lower semiconductor device 150 and the upper package substrate 210 in the first direction D1 and may overlap with the upper semiconductor device 250 in the second direction D2.

According to one or more example embodiments, the heat dissipation structure 300 may provide a path through which internal heat of the semiconductor package 10 may be dissipated to outside of the semiconductor package 10. The heat dissipation structure 300 may include a material having excellent thermal conductivity. The heat dissipation structure 300 may include a material having high thermal conductivity. For example, the heat dissipation structure 300 may include copper (Cu), silver (Ag), gold (Au), and aluminum (Al) but is not limited thereto.

According to one or more example embodiments, the heat dissipation structure 300 may be mounted above the external device 20, and a thermal interface material (TIM) 30 may be disposed above the heat dissipation structure 300. The semiconductor package 10 may be mounted on the external device 20, and heat generated in the semiconductor package 10 and the external device 20 may cause warpage. Due to the warpage of the semiconductor package 10, an upper surface 301 of the heat dissipation structure 300 may not be in contact with a lower surface of the TIM 30. By bringing the upper surface 301 of the heat dissipation structure 300 into contact with the lower surface of the TIM 30, heat within the semiconductor package 10 may be efficiently dissipated to outside.

According to one or more example embodiments, the heat dissipation structure 300 may be disposed such that the upper surface 301 of the heat dissipation structure 300 is inclined at a predetermined angle with respect to or toward the upper semiconductor device 250. The upper surface 301 of the heat dissipation structure 300 may be disposed to be inclined at the predetermined angle with respect to the upper surface US4 of the upper semiconductor device 250. The heat dissipation structure 300 may be disposed to be inclined at the predetermined angle with respect to the upper surface US3 of the upper package substrate 210. One end 301a of the upper surface 301 of the heat dissipation structure 300 may be disposed below the other end 301b of the upper surface 301 of the heat dissipation structure 300 in the first direction D1. The one end 301a of the upper surface 301 of the heat dissipation structure 300 may refer to an end of the upper surface 301 of the heat dissipation structure 300, which is disposed to be most adjacent to the upper semiconductor device 250 in the second direction D2. The other end 301b of the upper surface 301 of the heat dissipation structure 300 may refer to an end of the upper surface 301 of the heat dissipation structure 300, which is disposed opposite to the one end 301a of the upper surface 301 of the heat dissipation structure 300 in the second direction D2 and spaced apart farthest from the upper semiconductor device 250 in the second direction D2. In other words, the one end 301a of the upper surface 301 of the heat dissipation structure 300 may be disposed to be closer to the upper surface US1 of the lower package substrate 110 than the other end 301b of the upper surface 301 of the heat dissipation structure 300.

According to one or more example embodiments, the one end 301a of the upper surface 301 of the heat dissipation structure 300 may be disposed below the upper surface US4 of the upper semiconductor device 250 in the first direction D1, and the other end 301b of the upper surface 301 of the heat dissipation structure 300 may be disposed above the upper surface US4 of the upper semiconductor device 250 in the first direction D1. For example, a distance L1 in the first direction D1 between the one end 301a of the upper surface 301 of the heat dissipation structure 300 and the upper surface US4 of the upper semiconductor device 250 may be equal to a distance L2 in the first direction D1 between the other end 301b of the upper surface 301 of the heat dissipation structure 300 and the upper surface US4 of the upper semiconductor device 250.

According to one or more example embodiments, a slope of the upper surface 301 of the heat dissipation structure 300 may be constant with respect to the upper surface US3 of the upper package substrate 210. Accordingly, if the upper surface 301 of the heat dissipation structure 300 is tilted by the warpage of the semiconductor package 10, the upper surface 301 of the heat dissipation structure 300 may come into contact with the lower surface of the TIM 30.

According to one or more example embodiments, the heat dissipation structure 300 may be disposed such that a lower surface 302 of the heat dissipation structure 300 may be inclined with respect to the upper surface US3 of the upper package substrate 210. A distance in the first direction D1 between the lower surface 302 of the heat dissipation structure 300 and the upper surface US3 of the upper package substrate 210 may increase in the second direction D2.

According to one or more example embodiments, the heat dissipation structure 300 may be spaced apart from the upper semiconductor device 250 with a side surface of the upper semiconductor device 250 and a gap 260 in between in the second direction D2. The gap 260 may prevent interference between the upper semiconductor device 250 and the heat dissipation structure 300. For example, if warpage occurs in the semiconductor package 10 as illustrated in FIG. 3, the gap 260 may prevent interference between the upper semiconductor device 250 and the heat dissipation structure 300. As the heat dissipation structure 300 is disposed to be inclined above the upper package substrate 210, a width of the gap 260 in the second direction D2 may decrease in the first direction D1 toward an upper portion of the semiconductor package 10. Accordingly, it is possible to increase the efficiency of dissipating internal heat in a semiconductor package 10.

According to one or more example embodiments, the heat dissipation structure 300 may be coupled to the upper package substrate 210 through a plurality of connection bumps 310. The plurality of connection bumps 310 may be disposed between the heat dissipation structure 300 and the upper package substrate 210. The plurality of connection bumps 310 may be spaced apart from each other along the second direction D2 and may be spaced apart from each other along the third direction D3. For example, heights of the plurality of connection bumps 310 in the first direction D1 may increase in the second direction D2. In other words, each height of the plurality of connection bumps 310 in the first direction D1 may increase with increasing distance from the upper semiconductor device 250 in the second direction D2. Accordingly, the heat dissipation structure 300 on the plurality of connection bumps 310 may be disposed to be inclined with respect to the upper package substrate 210.

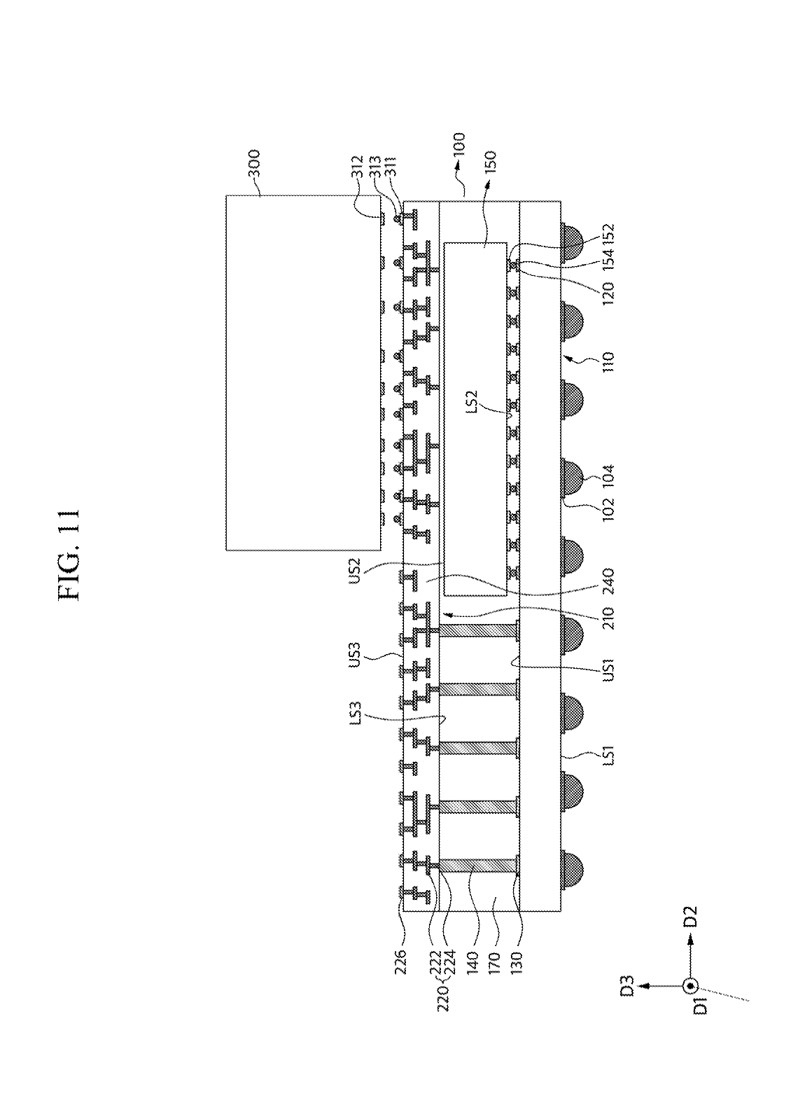

According to one or more example embodiments, the plurality of connection bumps 310 may be formed based on a plurality of pre-heat dissipation connection bumps 313 (see FIG. 11) being melted. Each of the plurality of connection bumps 310 above a second area 421 of the upper package substrate 210 may be formed based on the plurality of pre-heat dissipation connection bumps 313 being melted and combined. The plurality of connection bumps 310 above a third area 422 of the upper package substrate 210 may be formed based on the plurality of pre-heat dissipation connection bumps 313 being melted. Accordingly, each volume of the plurality of connection bumps 310 above the second area 421 may be greater than each volume of the plurality of connection bumps 310 above the third area 422. The second area 421 may be disposed to be more adjacent to the upper semiconductor device 250 in the second direction D2 than the third area 422. The third area 422 may be disposed to be farther from the upper semiconductor device 250 in the second direction D2 than the second area 421. Furthermore, each width of the plurality of connection bumps 310 in the second direction D2 may decrease in the second direction D2 toward the heat dissipation structure 300 from the upper semiconductor device 250. In other words, each width of the plurality of connection bumps 310 in the second direction D2 may decrease with increasing distance from the upper semiconductor device 250 in the second direction D2. For example, each width of the plurality of connection bumps 310 in the second direction D2 above the second area 421 may decrease in the second direction D2.

According to one or more example embodiments, a plurality of first heat dissipation connection pads 311 may be disposed on the upper package substrate 210. The plurality of first heat dissipation connection pads 311 may be disposed on the upper surface US3 of the upper package substrate 210. The plurality of first heat dissipation connection pads 311 may be spaced apart from each other in the second direction D2 and the third direction D3. The plurality of first heat dissipation connection pads 311 may include a conductive material. For example, the plurality of first heat dissipation connection pads 311 may include at least one of copper (Cu), aluminum (Al), tin (Sn), indium (In), lead (Pb), zinc (Zn), nickel (Ni), gold (Au), silver (Ag), antimony (Sb), bismuth (Bi), and a combination thereof, but these are merely examples.

According to one or more example embodiments, a plurality of second heat dissipation connection pads 312 may be disposed below the heat dissipation structure 300. The plurality of second heat dissipation connection pads 312 may be disposed on the lower surface 302 of the heat dissipation structure 300. The plurality of second heat dissipation connection pads 312 may be spaced apart from the plurality of first heat dissipation connection pads 311 with at least some of the plurality of connection bumps 310 in between in the first direction D1. The number of the plurality of second heat dissipation connection pads 312 may correspond to the number of the plurality of first heat dissipation connection pads 311. The plurality of second heat dissipation connection pads 312 may correspond one-to-one with the plurality of first heat dissipation connection pads 311. The plurality of second heat dissipation connection pads 312 may include a conductive material and may include a material identical or similar to that of the plurality of first heat dissipation connection pads 311.

According to one or more example embodiments, the plurality of connection bumps 310 may be disposed such that lower portions of the plurality of connection bumps 310 are coupled to the plurality of first heat dissipation connection pads 311 and upper portions of the plurality of connection bumps 310 are coupled to the plurality of second heat dissipation connection pads 312. Some of the plurality of connection bumps 310 may be coupled to the plurality of first heat dissipation connection pads 311 and the plurality of second heat dissipation connection pads 312. For example, the plurality of connection bumps 310 above the second area 421 may be coupled to two of the first heat dissipation connection pads 311 and two of the second heat dissipation connection pads 312.

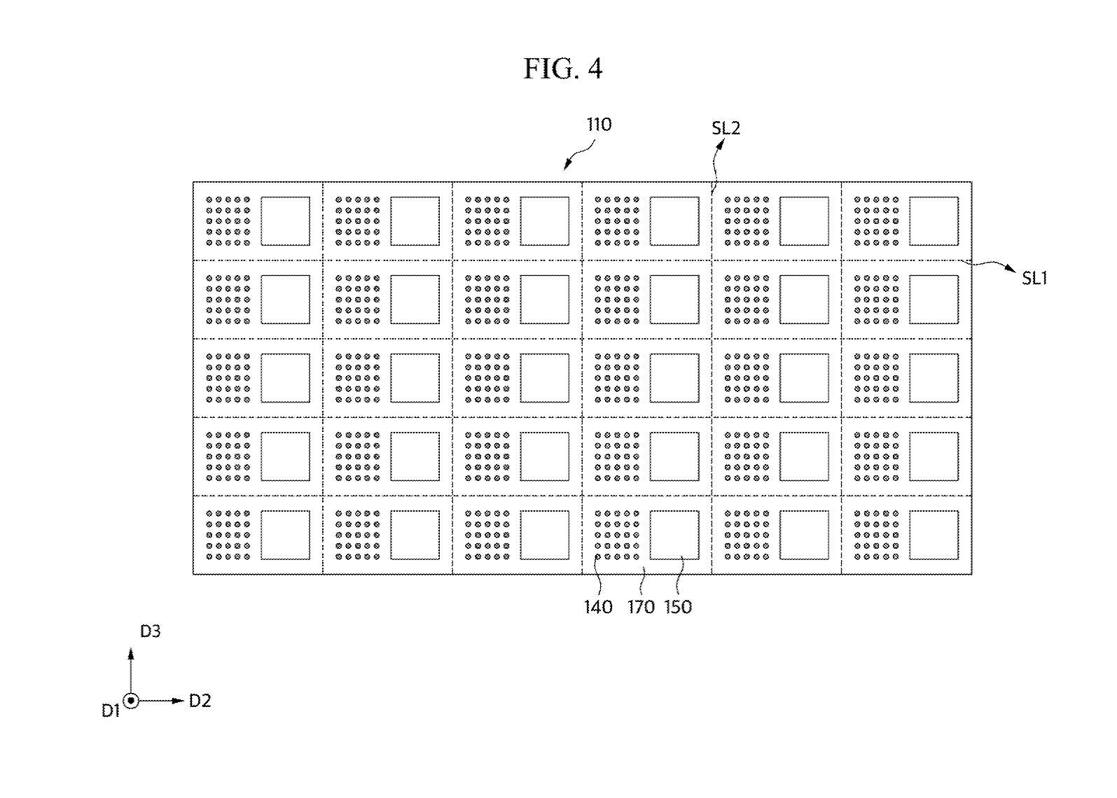

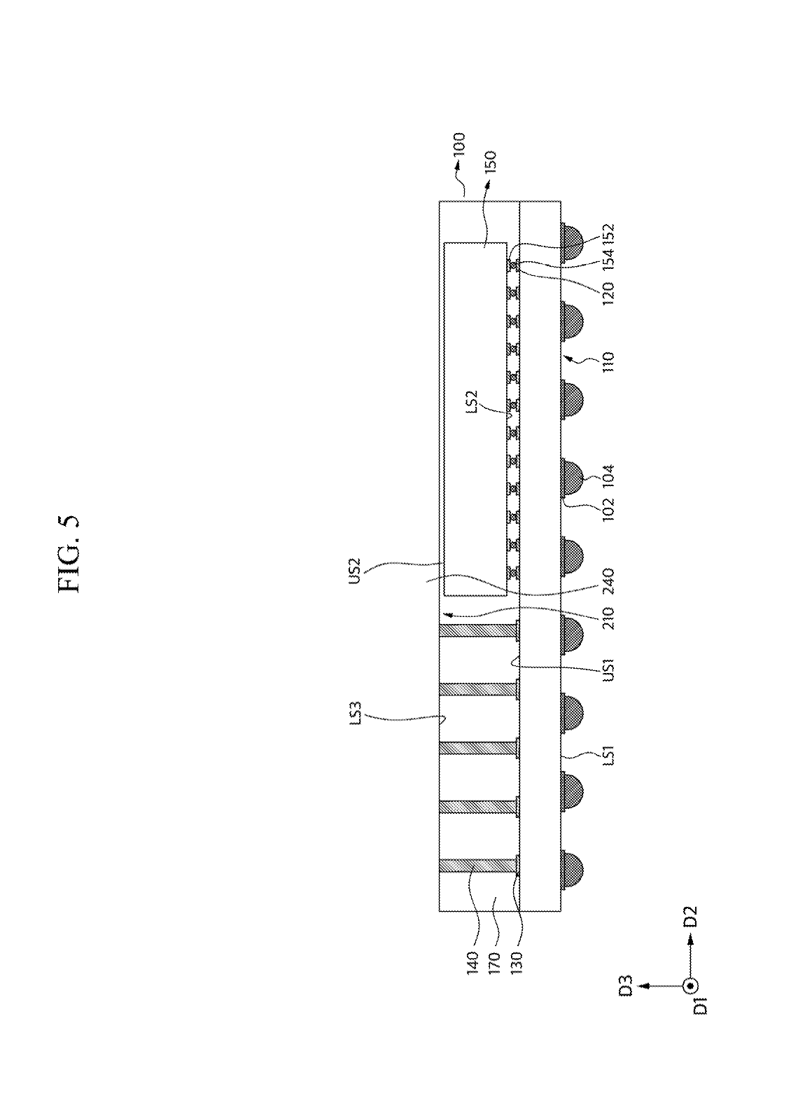

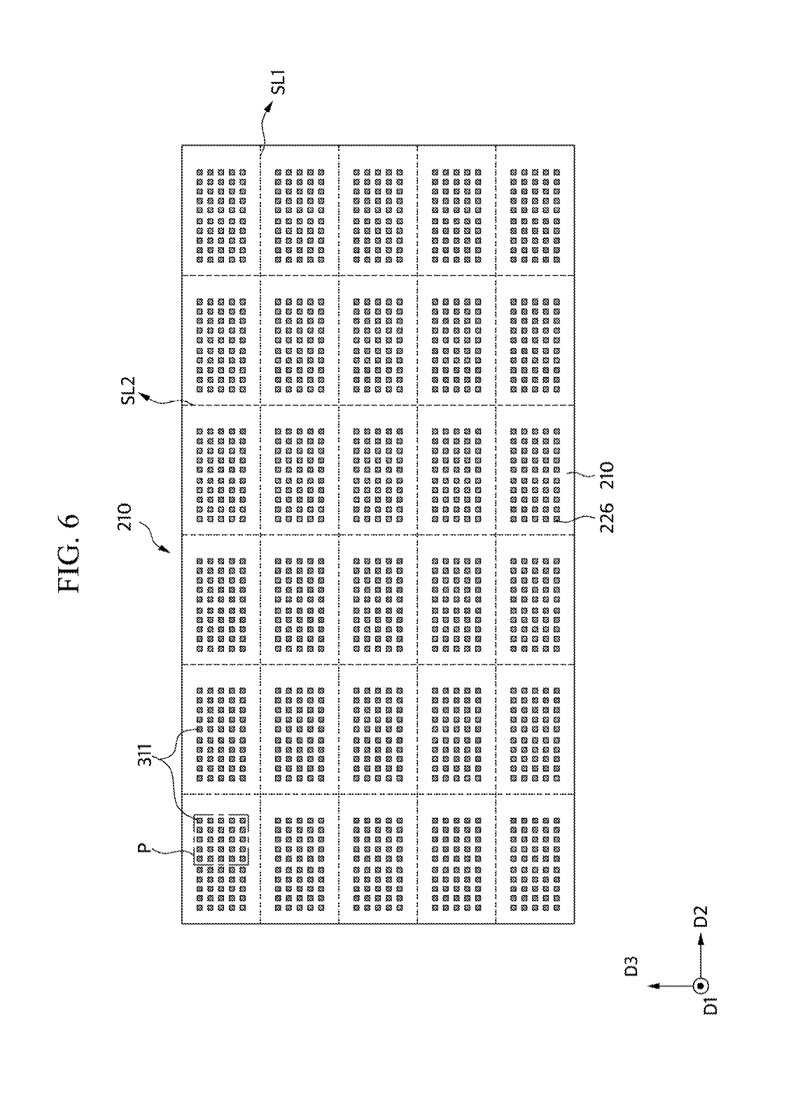

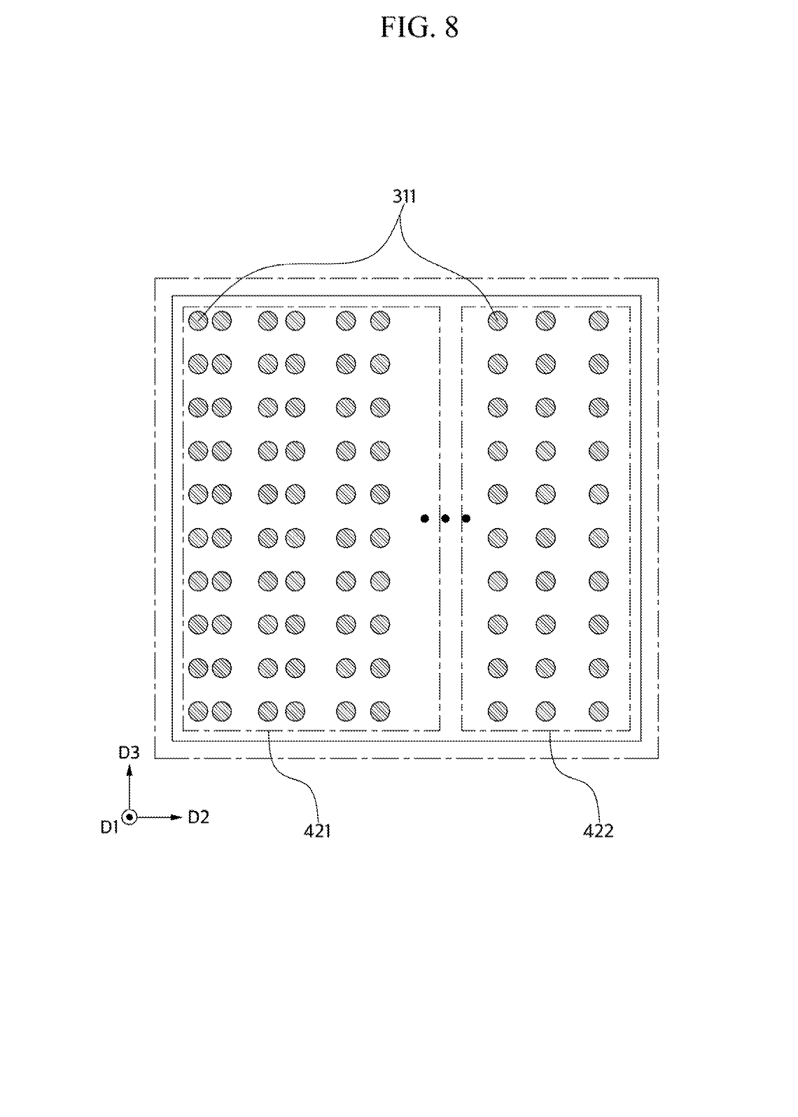

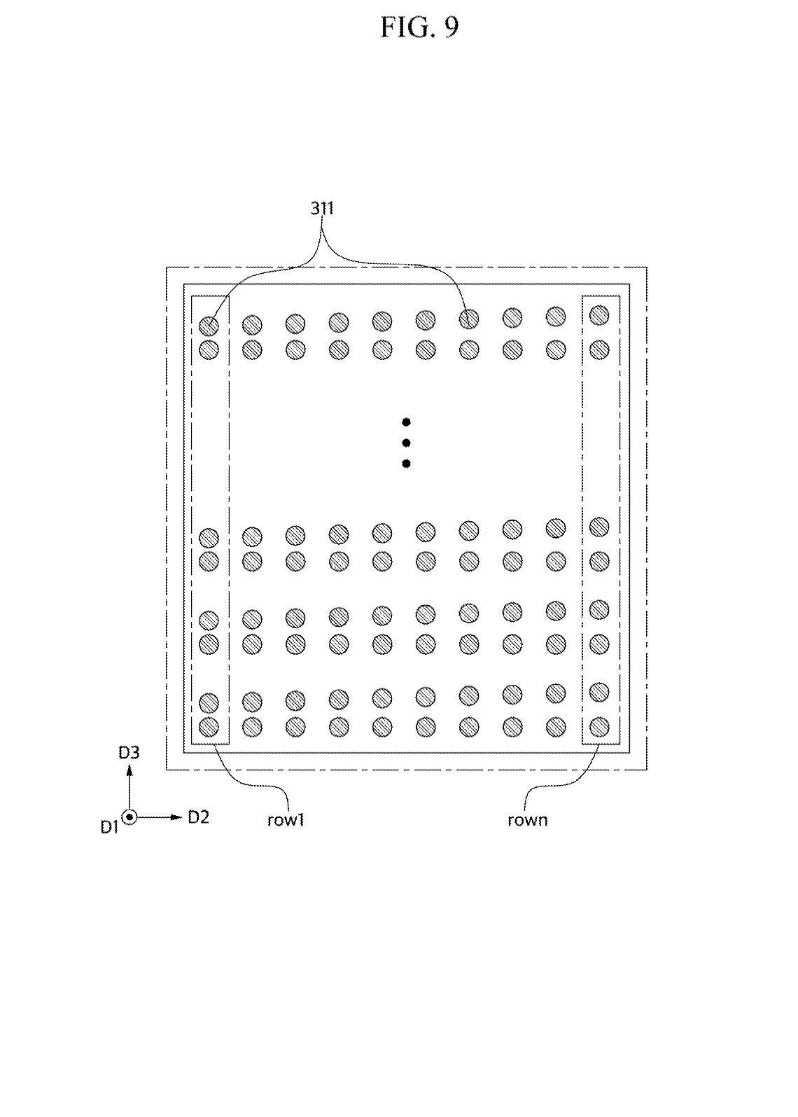

FIGS. 4, 5, 6, 7, 8, 9, 10, 11 and 12 are example diagrams of intermediate stages for illustrating a method of manufacturing the semiconductor package 10 of FIG. 2, according to one or more example embodiments, and more particularly, FIGS. 4, 6, and 10 are diagrams for illustrating a method of manufacturing the semiconductor package 10 at a panel level, according to one or more example embodiments, FIGS. 8 and 9 illustrate enlarged views of part P of FIG. 6, according to one or more example embodiments, and FIGS. 5, 7, 11, and 12 are diagrams of intermediate stages for illustrating a method of manufacturing the semiconductor package 10 at a panel level, according to one or more example embodiments.

Referring to FIGS. 4 and 5, the lower conductive structure 140, the lower semiconductor device 150, and the mold layer 170 surrounding the lower conductive structure 140 and the lower semiconductor device 150 may be disposed above the lower package substrate 110.

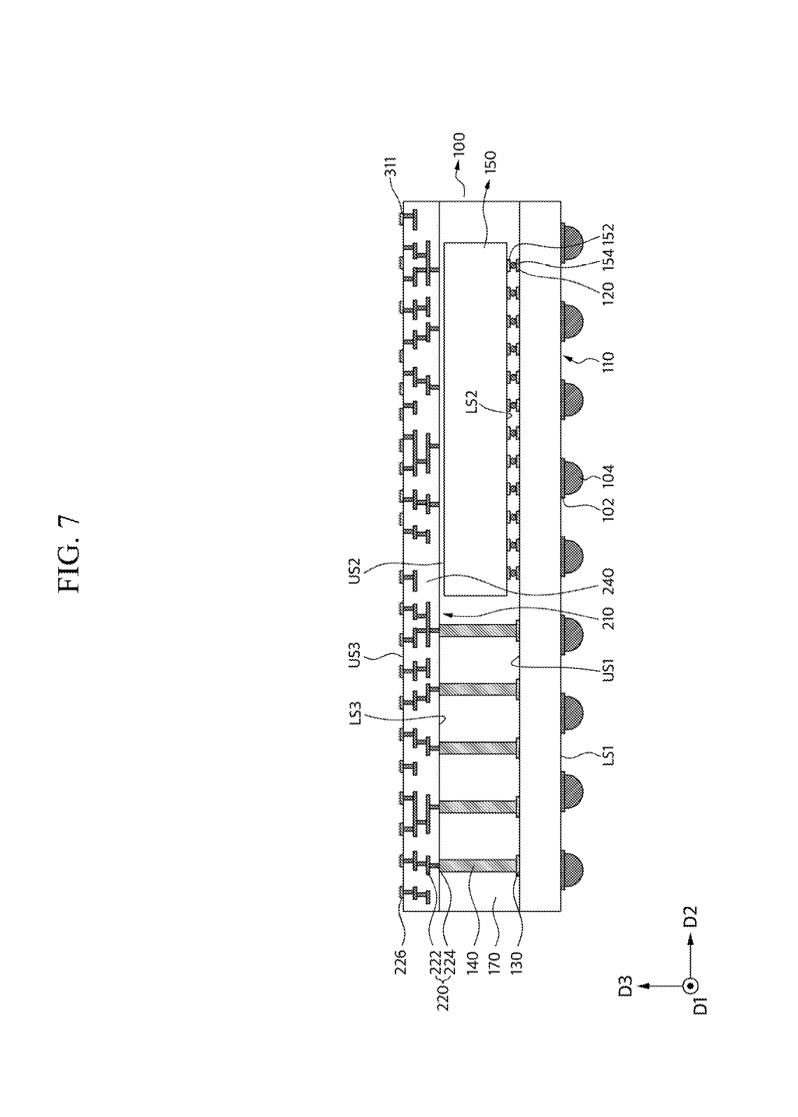

Referring to FIGS. 6 and 7, the plurality of wiring connection pads 226 and the plurality of first heat dissipation connection pads 311 may be disposed on the upper package substrate 210. The plurality of wiring connection pads 226 may be spaced apart from each other along the second direction D2 and the third direction D3 on a plane including the second direction D2 and the third direction D3. The plurality of first heat dissipation connection pads 311 may be spaced apart from each other along the second direction D2 and the third direction D3 on a plane including the second direction D2 and the third direction D3.

Referring to FIG. 8, a distance between two of the first heat dissipation connection pads 311 adjacent in the second direction D2 above the second area 421 may be shorter than a distance between two of the first heat dissipation connection pads 311 adjacent in the second direction D2 above the third area 422.

Referring to FIG. 9, the plurality of first heat dissipation connection pads 311 may be spaced apart from each other along the second direction D2 and the third direction D3. The plurality of first heat dissipation connection pads 311 may be disposed to form n rows spaced apart from each other in the second direction D2. Each of the n rows (row 1 through row n) may include the plurality of first heat dissipation connection pads 311 spaced apart along the third direction D3. For example, the plurality of first heat dissipation connection pads 311 may be disposed to form the n rows (row 1 through row n), which is from the first row (row 1) to the n-th row (row n), spaced apart from each other along the second direction D2.

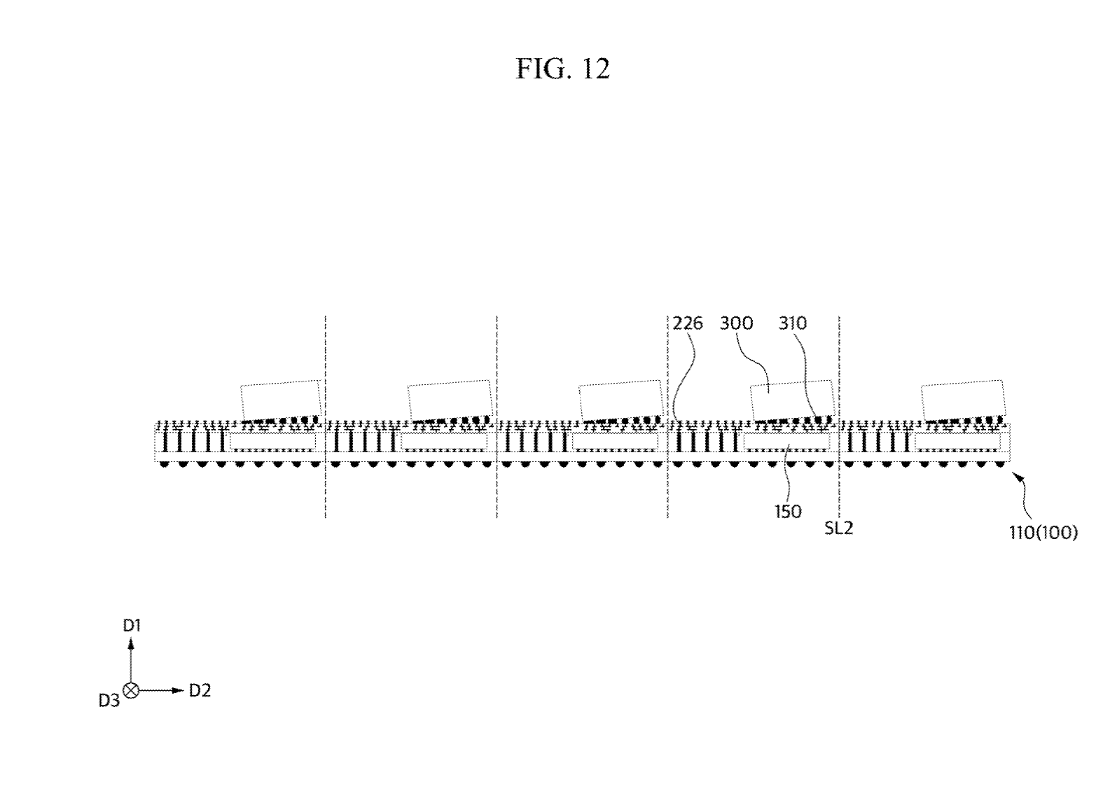

According to one or more example embodiments, the plurality of first heat dissipation connection pads 311 in each row (row 1 through row n) may be spaced apart from each other in the third direction D3. A distance between two of the plurality of first heat dissipation connection pads 311 adjacent in the third direction D3 in the (n-1)-th row may be shorter than a distance between two of the plurality of first heat dissipation connection pads 311 adjacent in the third direction D3 in the n-th row. Due to this, some of the plurality of pre-heat dissipation connection bumps 313 (see FIG. 11) disposed on the plurality of first heat dissipation connection pads 311 in a predetermined number of rows starting from the first row (row 1) may be melted and combined with each other to form the connection bumps 310 (see FIG. 12).

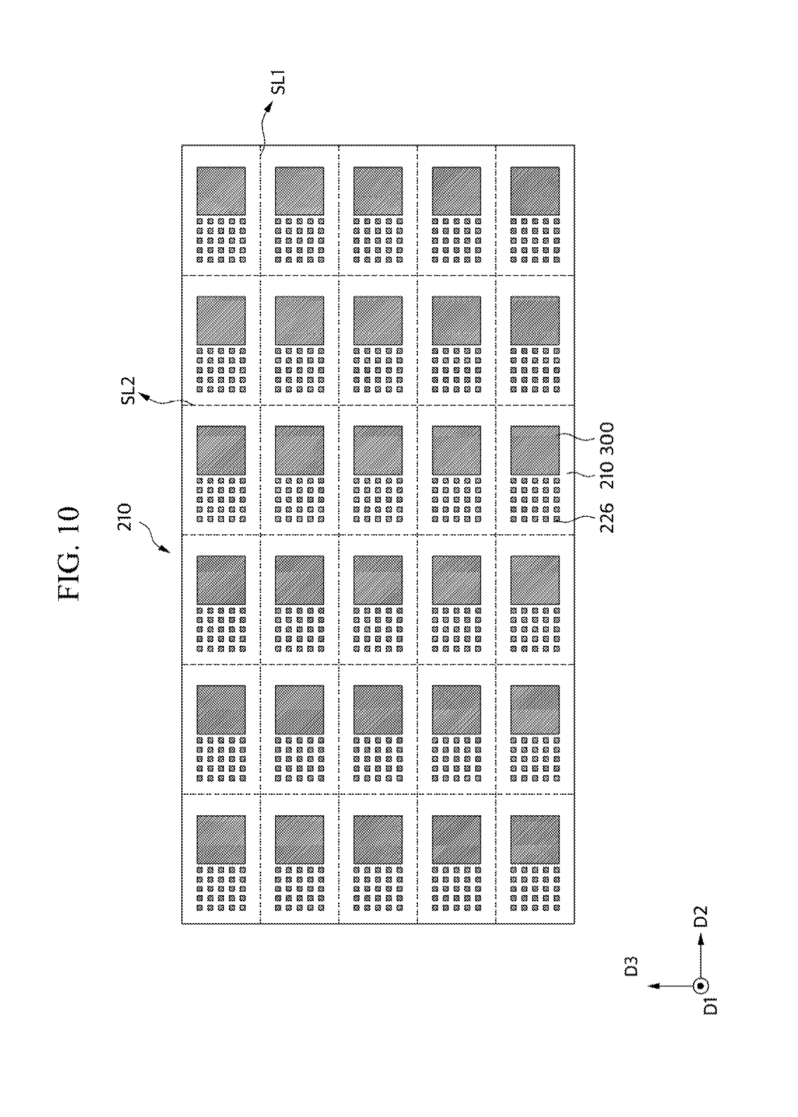

Referring to FIGS. 10, 11 and 12, the heat dissipation structure 300 may be mounted above the upper package substrate 210. One heat dissipation structure 300 may be disposed above each area divided by sawing lines SL1 and SL2 on the upper package substrate 210 at a panel level. A first sawing line SL1 may be parallel to the second direction D2, and a second sawing line SL2 may be parallel to the third direction D3.

According to one or more example embodiments, the heat dissipation structure 300 may be mounted on the upper package substrate 210 based on the plurality of pre-heat dissipation connection bumps 313 being melted to combine the plurality of first heat dissipation connection pads 311 and the plurality of second heat dissipation connection pads 312. Based on some of the plurality of pre-heat dissipation connection bumps 313 being combined to form the plurality of connection bumps 310 due to arrangements of the plurality of first heat dissipation connection pads 311 and the plurality of second heat dissipation connection pads 312, the heat dissipation structure 300 may be mounted on the upper package substrate 210 with the upper surface 301 of the heat dissipation structure 300 inclined with respect to the upper surface US3 of the upper package substrate 210.

According to one or more example embodiments, the plurality of second heat dissipation connection pads 312 may be disposed to overlap with the plurality of first heat dissipation connection pads 311 corresponding thereto in the first direction D1. For example, a distance between two of the plurality of second heat dissipation connection pads 312 adjacent above the second area 421 may be shorter than a distance between two of the plurality of second heat dissipation connection pads 312 adjacent above the third area 422. The plurality of pre-heat dissipation connection bumps 313 may be disposed on the plurality of first heat dissipation connection pads 311.

According to one or more example embodiments, the upper semiconductor device 250 (see FIG. 2) may be mounted above the upper package substrate 210 through the wiring connection pad 226. The lower package substrate 110 and the upper package substrate 210 may be formed by cutting the structures of FIGS. 10 and 12 along the first sawing line SL1 and the second sawing line SL2.

While one or more example embodiments are particularly shown and described above, it will be apparent to those of ordinary skill in the art that various modifications and variations in form and details may be made therein without departing from the spirit and scope of the following claims.

What is claimed is:

1. A semiconductor package comprising:
a lower package comprising:
a lower package substrate; and
a lower semiconductor device above the lower package substrate;
an upper package on the lower package in a first direction intersecting with an upper surface of the lower package, the upper package comprising:
an upper package substrate on the upper surface of the lower package; and
an upper semiconductor device above an upper surface of the upper package substrate; and
a heat dissipation structure above the lower package and spaced apart from the upper semiconductor device in a second direction intersecting with the first direction ,
wherein an upper surface of the heat dissipation structure is inclined at an angle with respect to the upper semiconductor device.

2. The semiconductor package of claim 1, further comprising:
connection bumps between the heat dissipation structure and the upper package substrate and spaced apart from each other in the second direction, and
wherein respective heights of the connection bumps in the first direction increase as a distance between the respective one of the connection bumps and the upper semiconductor device increases in the second direction.

3. The semiconductor package of claim 2, wherein respective widths of the connection bumps in the second direction decrease as a distance between the respective one of the connection bumps and the upper semiconductor device increases in the second direction.

4. The semiconductor package of claim 2, further comprising:
first heat dissipation connection pads on the upper package substrate; and
second heat dissipation connection pads below the heat dissipation structure,
wherein each of the second heat dissipation connection pads is spaced apart from one of the first heat dissipation connection pads with at least one of the connection bumps in between, and
wherein at least one of the connection bumps is coupled to a plurality of the first heat dissipation connection pads and a plurality of the second heat dissipation connection pads.

5. The semiconductor package of claim 2, wherein the upper semiconductor device is positioned above a first area of the upper package substrate,
wherein the heat dissipation structure is above a second area of the upper package substrate adjacent to the first area in the second direction and above a third area of the upper package substrate spaced apart from the first area with the second area in between, and
wherein respective volumes of the connection bumps above the second area are greater than respective volumes of the connection bumps above the third area.

6. The semiconductor package of claim 2, wherein the upper semiconductor device is above a first area of the upper package substrate,
wherein the heat dissipation structure is above a second area of the upper package substrate adjacent to the first area in the second direction and above a third area of the upper package substrate spaced apart from the first area with the second area in between,
wherein a plurality of the connection bumps are above the second area, and
wherein respective widths of the plurality of the connection bumps in the second direction decrease as a distance between the respective one of the plurality of connection bumps and the upper semiconductor device in the second direction increases.

7. The semiconductor package of claim 1, wherein a distance between a lower surface of the heat dissipation structure and the upper surface of the upper package substrate in the first direction increases as a distance in the second direction from the upper semiconductor device increases.

8. The semiconductor package of claim 1, wherein the heat dissipation structure is spaced apart from a side surface of the upper semiconductor device in the second direction with a gap in between, and
wherein a width of the gap in the second direction decreases as a distance from the lower package in the first direction increases.

9. The semiconductor package of claim 1, wherein one end of the upper surface of the heat dissipation structure closest to the upper semiconductor device is closer to an upper surface of the lower package substrate than another end of the upper surface of the heat dissipation structure farthest from the upper semiconductor device.

10. The semiconductor package of claim 1, wherein one end of the upper surface of the heat dissipation structure closest to the upper semiconductor device is provided below an upper surface of the upper semiconductor device in the first direction, and
wherein another end of the upper surface of the heat dissipation structure farthest from the upper semiconductor device is provided above the upper surface of the upper semiconductor device in the first direction.

11. The semiconductor package of claim 10, wherein a distance in the first direction between the upper surface of the upper semiconductor device and the one end of the upper surface of the heat dissipation structure closest to the upper semiconductor device is equal to a distance in the first direction between the upper surface of the upper semiconductor device and the another end of the upper surface of the heat dissipation structure.

12. The semiconductor package of claim 1, wherein an upper surface of the upper semiconductor device is parallel to the upper surface of the upper package substrate, and
wherein the upper surface of the heat dissipation structure is inclined at the angle with respect to the upper surface of the upper semiconductor device.

13. The semiconductor package of claim 1, wherein the heat dissipation structure overlaps the lower semiconductor device and the upper package substrate in the first direction, and overlaps the upper semiconductor device in the second direction.

14. The semiconductor package of claim 1, wherein a slope of the upper surface of the heat dissipation structure is constant with respect to the upper surface of the upper package substrate.

15. The semiconductor package of claim 1, wherein the lower package further comprises a lower conductive structure penetrating at least a portion of the lower package substrate,
wherein the upper package substrate comprises:
a wiring line connected to the lower conductive structure; and
an insulating layer surrounding the wiring line, and
wherein the upper semiconductor device is electrically connected to the upper package substrate and is connected to the lower package substrate through the wiring line and the lower conductive structure.

16. A semiconductor package comprising:
a lower package comprising:
a lower package substrate; and
a lower semiconductor device above the lower package substrate;
an upper package on the lower package in a first direction intersecting with an upper surface of the lower package, the upper package comprising:
an upper package substrate on the upper surface of the lower package; and
an upper semiconductor device above an upper surface of the upper package substrate; and
a heat dissipation structure above the lower package and spaced apart from a side surface of the upper semiconductor device in a second direction intersecting with the first direction with a gap in between,
wherein a width of the gap in the second direction decreases as a distance from the lower package in the first direction increases, and
wherein one end of an upper surface of the heat dissipation structure closest to the upper semiconductor device is closer to an upper surface of the lower package substrate than another end of the upper surface of the heat dissipation structure farthest from the upper semiconductor device.

17. The semiconductor package of claim 16, further comprising:
connection bumps between the heat dissipation structure and the upper package substrate, and spaced apart from each other by a predetermined distance in the second direction,
wherein respective heights of the connection bumps in the first direction increase as a distance between the respective one of the connection bumps and the upper semiconductor device increases in the second direction, and
wherein a distance between a lower surface of the heat dissipation structure and the upper surface of the upper package substrate in the first direction increases as a distance from the upper semiconductor device in the second direction increases.

18. The semiconductor package of claim 17, further comprising:
first heat dissipation connection pads on the upper package substrate; and
second heat dissipation connection pads below the heat dissipation structure,
wherein each of the second heat dissipation connection pads is spaced apart from one of the first heat dissipation connection pads with at least one of the connection bumps provided in between, and
wherein at least one of the connection bumps is coupled to a plurality of the first heat dissipation connection pads and a plurality of the second heat dissipation connection pads.

19. The semiconductor package of claim 16, wherein the one end of the upper surface of the heat dissipation structure closest to the upper semiconductor device is below an upper surface of the upper semiconductor device in the first direction, and
wherein another end of the upper surface of the heat dissipation structure farthest from the upper semiconductor device is above the upper surface of the upper semiconductor device in the first direction.

20. A semiconductor package comprising:
a lower package comprising:
a lower package substrate; and
a lower semiconductor device above the lower package substrate;
an upper package stacked on the lower package in a first direction intersecting with an upper surface of the lower package, the upper package comprising:
an upper package substrate on the upper surface of the lower package; and
an upper semiconductor device above an upper surface of the upper package substrate;
a heat dissipation structure above the lower package and spaced apart from a side surface of the upper semiconductor device in a second direction intersecting with the first direction with a gap in between ;
connection bumps between the heat dissipation structure and the upper package substrate, and spaced apart from each other by a predetermined distance in the second direction;
an external connection pad on a lower surface of the lower package substrate and including a conductive material; and
an external connection terminal coupled to the external connection pad,
wherein respective lengths of the connection bumps in the first direction increase as a distance between the respective one of the connection bumps and the upper semiconductor device increases in the second direction,
wherein an upper surface of the heat dissipation structure is inclined at an angle with respect to the upper semiconductor device,
wherein one end of the upper surface of the heat dissipation structure closest to the upper semiconductor device is below an upper surface of the upper semiconductor device in the first direction, and
wherein another end of the upper surface of the heat dissipation structure farthest from the upper semiconductor device is above the upper surface of the upper semiconductor device in the first direction.
